(19) United States
(12) Patent Application Publication
(10) Pub. No.: US 2002/0168828 A1
(43) Pub. Date: Nov. 14, 2002

(54) Method of reducing threshold voltage shifting of a gate

(76) Inventors: Kuan-Lun Cheng, Kao-Hsiung City (TW); Tony Lin, Hsin-Chu City (TW)

Correspondence Address: NAIPO (NORTH AMERICA INTERNATIONAL PATENT OFFICE), P.O. BOX 506, MERRIFIELD, VA, 22116, US

(21) Appl. No.: 09/851,579

(22) Filed: May 10, 2001

(51) Int. Cl. H01L 21/336

(52) U.S. Cl. 438/303

(57) ABSTRACT

A gate oxide is formed on a silicon substrate of a semiconductor wafer. Fluorine (F) ions are doped into the gate oxide or the silicon substrate. A conductive layer is then formed on the gate oxide and an etching process is performed to etch the conductive layer to form a gate on the surface of the silicon substrate. Next, a low-temperature deposition process is performed in a hydrogen-containing environment to form silicon nitride layer on a surface of the silicon substrate, walls of the gate, and top of the gate. Finally, an etch back process is performed on the silicon nitride layer to form a spacer around the walls of the gate, followed by an ion implantation process to form a source and drain on the surface of the silicon substrate adjacent to the gate.

### FIELD OF THE INVENTION

The present invention relates to a method of reducing threshold voltage shifting of a gate.

### DESCRIPTION OF THE PRIOR ART

During semiconductor fabrication, MOS transistors formed in the fabrication experience several high temperature processes. The annealing processes for the driving-in of dopants to form a heavily doped drain (the temperature in such a process is generally between 800-1000° C.) is one such process. Silicon nitride depositions by way of a low pressure chemical vapor deposition (LPCVD) (temperatures between 750-800° C.), and rapid thermal processes during salicide fabrication (with temperatures between 700-850° C.) are other examples of such high-temperature processes.

These high temperature processes cause dopants in doped regions to gain higher energies and diffuse. Therefore, the region of a highly doped drain largely increases, shrinking the channel length and inducing hot electron effects and electrical breakdown. This leads to the phenomenon of threshold voltage shifting, leakage current and soft errors. These situations become more and more serious when the fabrication width is less than 0.18 μm. Therefore, when performing high-temperature thermal processes and deposition processes, a low thermal budget technique is general used to reduce the dopant diffusion in the doped drain. For example, a low-temperature rapid thermal nitridation process (RTN) is widely applied in semiconductor fabrication to deposit a silicon nitride layer that is used as a spacer.

Please refer to FIG. 1 to FIG. 5. FIG. 1 to FIG. 5 are schematic diagrams of a method for fabricating a MOS transistor according to the prior art. As shown in FIG. 1, a semiconductor wafer 10 comprises a silicon substrate 12, an active area 14 set in the surface of the silicon substrate 12, and field oxide (FOX) 16 functioning as an insulation material to surround and isolate each active area 14. The prior art first oxidizes the silicon of the silicon substrate 12 in the active area 14 to form silicon oxide, which is used as a gate oxide 18. A doped polysilicon layer is then equally deposited on the surface of the semiconductor wafer 10 to serve as a conductive layer 20, and which covers the surface of the gate oxide 18 and field oxide 16.

As shown in FIG. 2, a photoresist layer 22 is then coated on the surface of the conductor layer 20, followed by a photo-etching process (PEP) to define a gate 24 structure in the gate oxide 18 and conductive layer 20. Then, after removing the photoresist layer 22, the gate 24 is used as a mask to perform a first ion implantation process 26 with a low dopant concentration in the semiconductor wafer 10 in order to form a lightly doped drain 28, as shown in FIG. 3.

As shown in FIG. 4, the semiconductor wafer 10 is then put in a thermal furnace (not shown), and silane (SiH₄), nitrogen (N₂) and hydrogen (H₂) are injected in the furnace. An RTN process, with a temperature below 700° C., is performed for 60 seconds to equally deposit a silicon nitride layer 30 on the surface of the semiconductor wafer 10, which covers the gate 24. Next, an etch back process is performed on the surface of the semiconductor wafer 10. That is, an anisotropic etching process is used to form a spacer 32 on the surface of the silicon substrate 12 adjacent to the gate 24, as shown in FIG. 5. Finally, the spacer 32 and gate 24 are used as a mask to perform a second ion implantation process with high dopant concentration and deeper depth on the semiconductor wafer 10 in order to form a source 36 and drain 38, and to complete the fabrication process of the MOS transistor according to the prior art.

However, when using the RTN process to deposit the silicon nitride layer 30 that is used to form the spacer 32, silane, nitrogen and hydrogen gases are required as processing gases. The depositing environment thus contains a large amount of hydrogen atoms. The hydrogen atoms enter the silicon substrate 12 and gate oxide 18 and react with the silicon atom therein, forming Si-H bonds, or becoming trapped in the crystalline silicon structure. These situations cause problems in the gate oxide 18, such as interface states, trapped charge, and structural defects. This may cause threshold voltage (Vₜ) shifting of gate 24, thereby seriously affecting the yield and the reliability of the semiconductor wafer 10.

### SUMMARY OF THE INVENTION

It is therefore a primary objective of the present invention to provide a MOS transistor fabrication method for reducing gate threshold voltage shifting, to solve the above-mentioned problems.

The present invention provides a method for reducing threshold voltage shift of a gate on a semiconductor wafer. The method first forms a gate oxide on the silicon substrate of the semiconductor wafer, and dopes fluorine (F) ions into the gate oxide or the silicon substrate. A conductive layer is then formed on the gate oxide, and an etching process is performed to the conductive layer to form the gate on the surface of the silicon substrate. Next, a deposition process is performed in a hydrogen-containing environment to form a silicon nitride layer on a surface of the silicon substrate, walls of the gate, and top of the gate. Finally, an etching back process is performed on the silicon nitride layer to form a spacer around the walls of the gate, followed by utilizing an ion implantation process to form a source and drain on the surface of the silicon substrate adjacent to the gate and complete the fabrication process of the MOS transistor according to the present invention.

The present invention uses the fluorine ion doping of the silicon substrate or gate oxide to inhibit reactions between silicon atoms in the substrate and gate oxide and environmental hydrogen during silicon nitride layer deposition, thereby avoiding the threshold voltage shifting caused by defects in gate oxide.

These and other objectives of the present invention will no doubt become obvious to those of ordinary skill in the art after reading the following detailed description of the preferred embodiment, which is illustrated in the various figures and drawings.

### BRIEF DESCRIPTION OF THE DRAWINGS

FIG. 1 to FIG. 5 are schematic diagrams of a fabrication method for a MOS transistor according to the prior art.

FIG. 6 to FIG. 11 are schematic diagrams of a fabrication method for a MOS transistor according to the present invention.

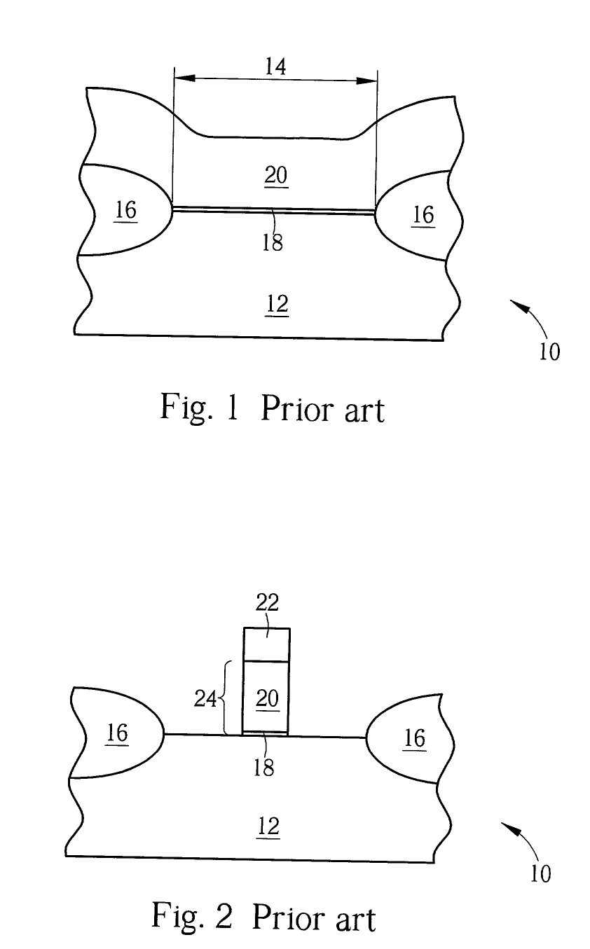

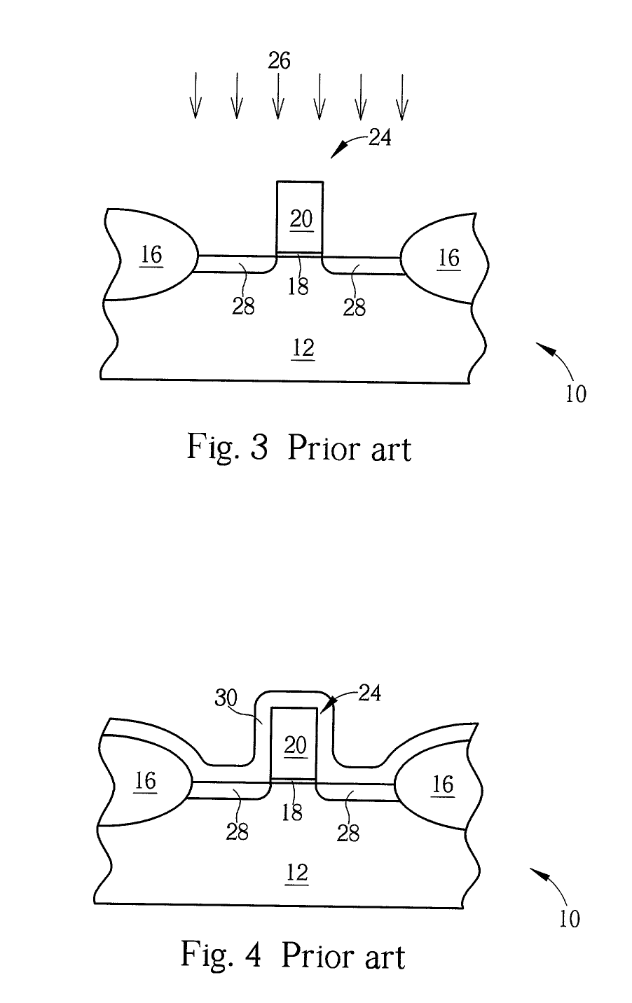

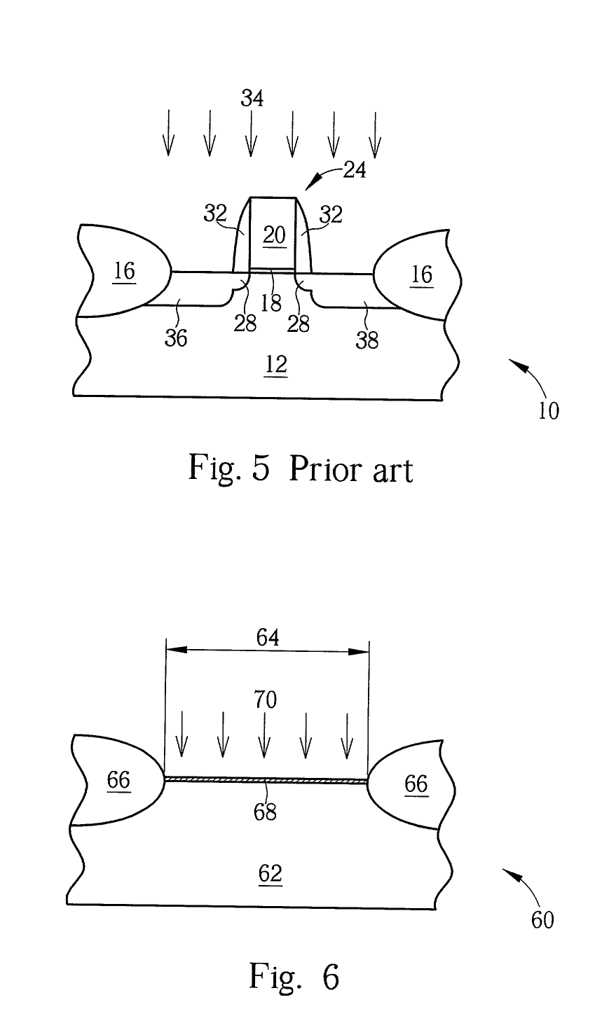

### DESCRIPTION OF THE PREFERRED EMBODIMENT

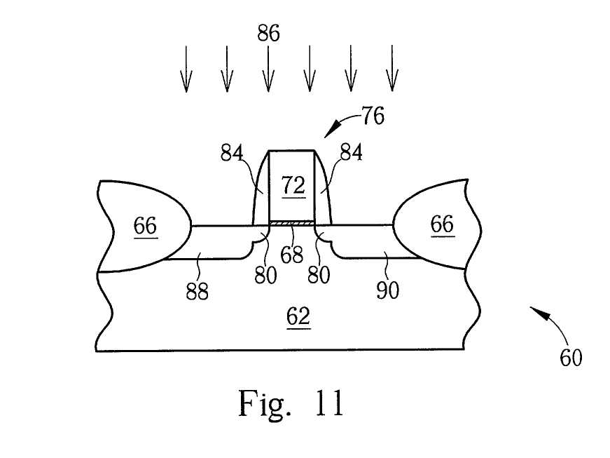

Please refer to FIG. 6 to FIG. 11. FIG. 6 to FIG. 11 are schematic diagrams for fabrication of a MOS transistor on a semiconductor wafer 60 according to the present invention. As shown in FIG. 6, the semiconductor wafer 60 comprises a silicon substrate 62, an active area 64 set on the surface of the silicon substrate 62, and field oxides (FOX) 66 functioning as an insulator to isolate and surround each active area 64. The present invention, however, is not limited to using only field oxide isolation. Other insulating methods, such as shallow trench isolation (STI) structures, are also applicable to the present invention.

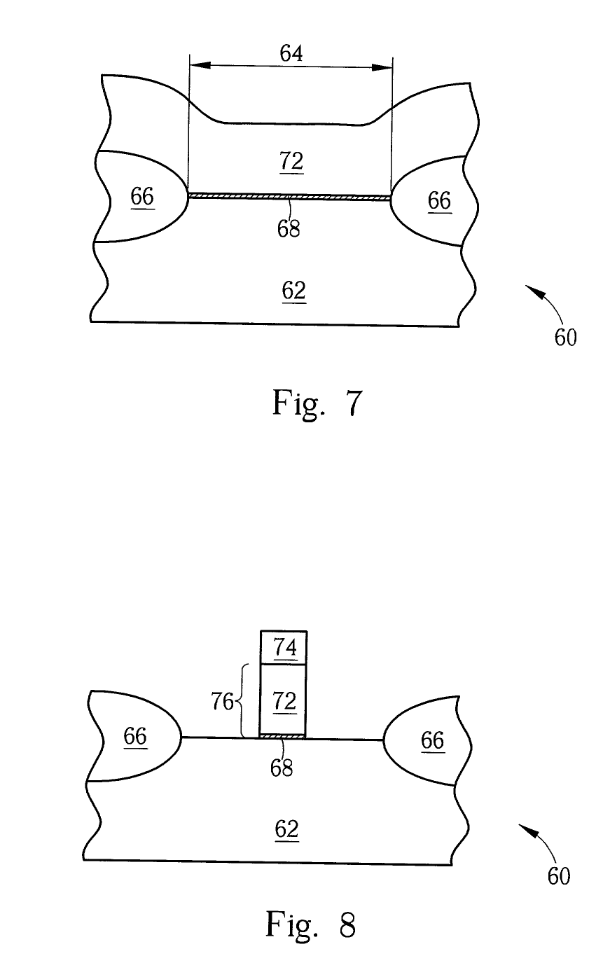

The present invention first places the semiconductor wafer 60 in an oxidation furnace, and a dry oxidation process oxidizes the silicon of the active area 64 on the surface of the silicon substrate 62 to form an isolating silicon oxide, with a thickness of 100-250 angstroms, functioning as a gate oxide 68. Next, an ion implantation, plasma doping, or remote plasma treatment method is used to perform a fluorine ion doping process on the semiconductor wafer 60. That is, fluorine is doped into the gate oxide 68, or the silicon substrate 62, to make the fluorine react with the silicon atoms or oxygen atom therein, thus forming Si-F and O-F bonds. The fluorine ion doping process 70 may also be performed before the gate oxide 68 formation. The implantation energy of the fluorine ions is about 6 to 10 KeV. As shown in FIG. 7, a low pressure chemical vapor deposition (LPCVD) technique is then used on the semiconductor wafer 60 to deposit a conductive layer 72, which is composed of a doped polysilicon layer, or a stacked structure with a doped silicon layer and a silicide layer.

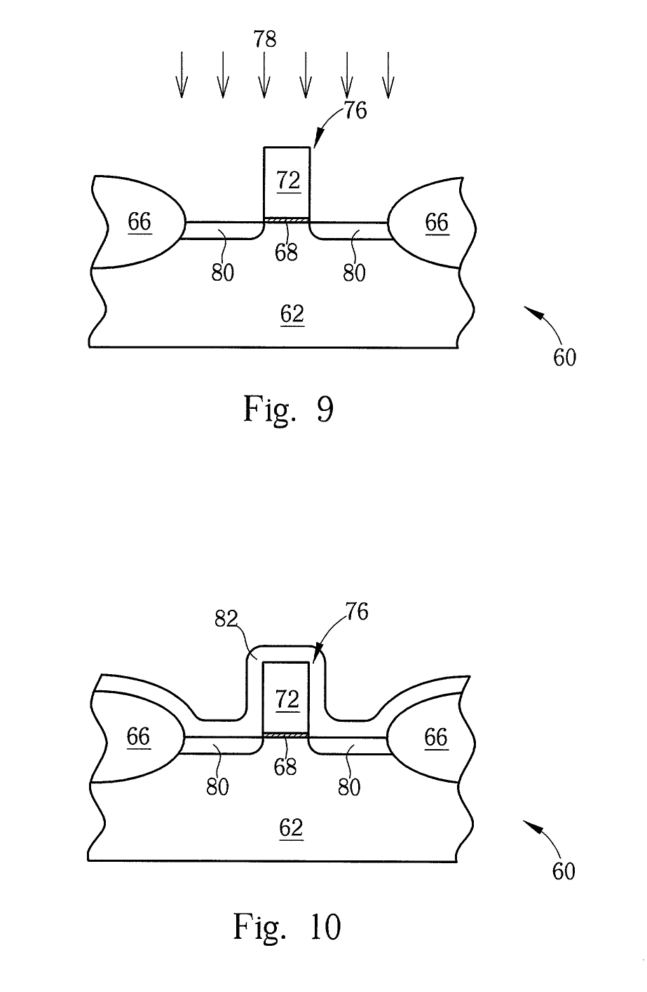

As shown in FIG. 8, a photoresist layer 74 is then formed on the surface of the conductive layer 72. A first photo-etching process (PEP) is used to define a gate 76 structure in the gate oxide 68 and doped polysilicon layer 70. As shown in FIG. 9, after removing the photoresist layer 74, the gate 76 is used as a mask to perform a low-concentration ion implantation process 78 on the semiconductor wafer 60 to form lightly doped drains 80. Taking a P-type substrate as an example, the implantation dosage is about 10¹³/cm², and is primarily used to prevent short channel effects.

As shown in FIG. 10, the semiconductor wafer 60 is then placed in a thermal furnace (not shown), and silane (SiH₄), nitrogen (N₂), and hydrogen (H₂) are injected in the furnace. An RTN process with a temperature that is below 700° C. is performed for 60 seconds to equally deposit a silicon nitride layer 82 that covers the surface of the silicon substrate 62, the walls of the gate 76, and the top of the gate 76.

Finally, as shown in FIG. 1, an etch back process is performed on the semiconductor wafer 60. That is, an anisotropic etching process is used to remove a portion of the silicon nitride layer 82. The remaining silicon nitride layer 82 on the walls surrounding the gate 76 forms a spacer 84. Both the spacer 84 and the gate 76 function as masks to perform a high-concentration and deeper depth second ion implantation process 86 on the semiconductor wafer 60 to form a source 88 and a drain 90. The implantation concentration is about 10¹⁵/cm². The fabrication process of the MOS transistor is thus completed according to the present invention. After performing the first 78 and second 86 ion implantation processes, an annealing process at 850 to 1050° C. is usually performed to allow driving-in of the dopants and to form a diffusion region, and to simultaneously recover a portion of the silicon structure damaged by the implantation process.

Because the present invention uses ion implantation or plasma doping methods to dope fluorine ions into the silicon substrate 62 or gate oxide 68 before or after the gate oxide 68 formation, the fluorine ions react with the silicon or oxygen atom in the silicon substrate 62 and gate oxide 68 to form stronger Si-F and O-F bonds. Thus, in subsequent processes of depositing the silicon nitride layer 82 by way of an RTN process, the hydrogen atoms in the RTN depositing environment are unable to react with the silicon atoms in the silicon substrate 62 and gate oxide 68 to form Si-H because the Si-F and O-F bonds are stronger than Si-H bonds. The present method thus avoids problems such as interface states, trapped charge, and structural defects in the gate oxide 68 to maintain the quality of the gate oxide 68 and efficiently inhibit the phenomenon of threshold voltage shifting of gate.

In contrast to the prior art method of gate fabrication, the present invention dopes fluorine ions into the gate oxide and the silicon substrate to avoid problems such as hydrogen crystal defects caused by the reaction between the silicon atom and hydrogen atoms during subsequent silicon nitride depositions with low thermal budgets. Therefore, the present invention can avoids threshold voltage shifting of the gate and increases the reliability of the semiconductor wafer. Additionally, with the fluorine ion doping process, the gate oxide has a tighter distribution and better electrical qualities against breakdown voltage when performing charge to breakdown tests (Qbd). Moreover, the doping process of the present method is very simple and compatible with the current ULSI processes, without requiring an additional photo layer.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A method for reducing threshold voltage shift of a gate on a semiconductor wafer, the semiconductor wafer comprising a silicon substrate, the method comprising:
forming an insulation layer on the silicon substrate;
doping fluorine (F) ions into the insulation layer or into the silicon substrate;
forming a conductive layer on the insulation layer;
performing an etching process to the insulation layer and the conductive layer to form the gate on the silicon substrate, the gate comprising a gate insulator and a gate electrode stacked on the gate insulator;
performing a deposition process in a hydrogen-containing environment to form a silicon nitride layer on a surface of the silicon substrate, walls of the gate, and top of the gate; and
performing an etching back process to the silicon nitride layer to form a spacer around the walls of the gate.

2. The method of claim 1 wherein the insulation layer comprises silicon dioxide.

3. The method of claim 1 wherein the conductive layer comprises doped poly-silicon.

4. The method of claim 1 wherein the fluorine ions will bond with silicon atoms in the insulation layer or in the silicon substrate to retard hydrogen ions in the deposition process bond with the silicon atoms in the insulation layer or in the silicon substrate so as to reduce threshold voltage shift of the gate.

5. The method of claim 1 wherein the fluorine ions are doped into the insulation layer or into the silicon substrate by performing an ion implantation process, using a plasma doping method, or performing a fluorine-containing plasma treatment.

6. The method of claim 1 wherein the deposition process is a rapid thermal nitridation (RTN) process, the process is performed at a temperature below 700° C.

7. A method for improving qualities of a gate oxide on a semiconductor wafer, the semiconductor wafer comprising a silicon substrate, the method comprising:
doping fluorine (F) ions into the silicon substrate to bond the fluorine ions with silicon atoms in the silicon substrate;
forming an oxide layer on the silicon substrate;
forming a conductive layer on the oxide layer;
performing an etching process to the oxide layer and the conductive layer to form a gate on the silicon substrate, the gate comprising the gate oxide and a gate electrode stacked on the gate oxide;
performing a low temperature rapid thermal nitridation (RTN) process in a hydrogen-containing environment to form a silicon nitride layer on a surface of the silicon substrate, walls of the gate, and top of the gate; and
performing an etching back process to the silicon nitride layer to form a spacer around the walls of the gate.

8. The method of claim 7 wherein the oxide layer comprises silicon dioxide.

9. The method of claim 7 wherein the conductive layer comprises doped poly-silicon.

10. The method of claim 7 wherein the fluorine ions are doped into the silicon substrate by performing an ion implantation process, using a plasma doping method, or performing a fluorine-containing plasma treatment.

11. The method of claim 7 wherein the low temperature rapid thermal nitridation process is performed at a temperature below 700° C.
